(19) United States
(12) Patent Application Publication
(10) Pub. No.: US 2020/0012017 A1
(43) Pub. Date: Jan. 9, 2020

(54) OPTICAL PART, METHOD FOR PRODUCING OPTICAL PART, AND IMAGE DISPLAY APPARATUS

(71) Applicant: SONY CORPORATION, TOKYO (JP)

(72) Inventor: KAZUHITO SHIMODA, KANAGAWA (JP)

(21) Appl. No.: 16/491,010

(22) PCT Filed: Feb. 16, 2018
(86) PCT No.: PCT/JP2018/005498

§ 371 Date: Sep. 4, 2019

(30) Foreign Application Priority Data
Mar. 16, 2017 (JP) 2017-050816

(51) Int. Cl. G02B 1/115; G02B 3/08; C23C 16/455; C23C 16/40; C23C 16/34

(52) U.S. Cl. CPC G02B 1/115; G02B 3/08; C23C 16/34; C23C 16/403; C23C 16/45525

(57) ABSTRACT

To achieve the above described purpose, an optical part according to an embodiment of the present technology includes an optical section and a multi-layer film. The optical section includes a first surface and a second surface constituting a recessed section or a protruded section in cooperation with the first surface. The multi-layer film is formed on the first surface and the second surface, and includes an absorption layer for absorbing light and an upper layer including low refractive index material covering the absorption layer.

### TECHNICAL FIELD

The present technology relates to an optical part such as a lens, a method for producing the optical part, and an image display apparatus.

### BACKGROUND ART

Patent Literature 1 discloses a method for fabricating a Fresnel lens capable of preventing a problem caused by generation of stray light in forming an image. According to this fabrication method, primary films are first formed only on a lens surfaces of the Fresnel lens. Invalid light absorbing films are formed on the lens surfaces on which the primary films have been formed, and non-lens surfaces on which the primary films have not been formed. By removing the primary films from the lens surfaces, the invalid light absorbing films remain only on the non-lens surfaces. This makes it possible to prevent generation of stray light caused by light passing through the non-lens surfaces (see paragraphs [0001] and [0058] to [0073] of the specification, and FIG. 1, etc. of Patent Literature 1).

### CITATION LIST

### Patent Literature

Patent Literature 1: JP H08-136707A

### DISCLOSURE OF INVENTION

### Technical Problem

Technologies of easily producing optical parts such as Fresnel lenses that suppress generation of such stray light have been desired.

In view of the circumstances as described above, a purpose of the present technology is to provide an optical part, a method of producing the optical part, and an image display apparatus. The optical part is easily produced, and the optical part is capable of suppressing generation of stray light.

### Solution to Problem

To achieve the above described purpose, an optical part according to an embodiment of the present technology includes an optical section and a multi-layer film.

The optical section includes a first surface and a second surface constituting a recessed section or a protruded section in cooperation with the first surface.

The multi-layer film is formed on the first surface and the second surface, and includes an absorption layer for absorbing light and an upper layer including low refractive index material covering the absorption layer.

In the optical part, the multi-layer film is formed on the first and second surfaces. The multi-layer film includes an absorption layer for absorbing light and an upper layer including low refractive index material covering the absorption layer. This makes it possible to absorb light and prevent reflection of the light on the first and second surfaces, and it is possible to sufficiently suppress generation of stray light. In addition, it is easy to produce the optical part because it is only necessary to form the same films on the first and second surfaces.

The first surface may have a predetermined function related to incident light.

For example, this makes it possible to easily produce a lens or the like that suppresses generation of stray light.

The multi-layer film may have optical absorption property depending on an incident angle of the light.

For example, this makes it possible to suppress absorption of light incident on the first surface and increase absorption of light incident on the second surface.

The multi-layer film may have higher absorptance with respect to internal light that is incident on the multi-layer film from an inside of the optical section at the incident angle of 50° or more, than absorptance with respect to external light that is incident on the multi-layer film from an outside of the optical section at the incident angle of approximately 0°.

For example, this makes it possible to sufficiently suppress stray light caused by internal light having an incident angle of 50° or more.

The multi-layer film may have higher absorptance with respect to internal light that is incident on the multi-layer film from an inside of the optical section, as the incident angle increases.

This makes it possible to sufficiently suppress generation of stray light caused by internal light having a large incident angle.

The multi-layer film may have reflectance of 4% or less with respect to external light that is incident on the multi-layer film from an outside of the optical section at the incident angle of 40° or less.

For example, this makes it possible to suppress loss caused by reflection of external light having an incident angle of 40° or less. In addition, it is also possible to suppress generation of stray light.

The absorption layer may include a metal oxide, a metal nitride, or carbon.

This makes it possible to absorb light and prevent reflection of light, and it is possible to sufficiently suppress generation of stray light.

The absorption layer may include an oxide of aluminum, or titanium nitride.

This makes it possible to absorb light and prevent reflection of light, and it is possible to sufficiently suppress generation of stray light.

The absorption layer may have a thickness of 5 nm or more and 25 nm or less.

This makes it possible to absorb light and prevent reflection of light, and it is possible to sufficiently suppress generation of stray light.

The upper layer may include the low refractive index material having a refractive index of 1.5 or less.

This makes it possible to absorb light and prevent reflection of light, and it is possible to sufficiently suppress generation of stray light.

The upper layer may have a thickness of 50 nm or more and 150 nm or less.

This makes it possible to absorb light and prevent reflection of light, and it is possible to sufficiently suppress generation of stray light.

The multi-layer film may include a lower layer interposed between the optical section and the absorption layer.

This makes it possible to control light absorbability and light reflectivity of the multi-layer film.

The lower layer may include material having a refractive index of 1.5 or more.

This makes it possible to control light absorbability and light reflectivity of the multi-layer film.

The lower layer may have a thickness of 10 nm or more and 100 nm or less.

This makes it possible to control light absorbability and light reflectivity of the multi-layer film.

The optical section may be a Fresnel lens including a lens surface that is the first surface, and a non-lens surface that is the second surface.

This makes it possible to easily produce a Fresnel lens capable of suppressing generation of stray light.

The absorption layer may be a metal oxide, and an oxygen addition amount in a region formed on the first surface may be larger than an oxygen addition amount in a region formed on the second surface.

This makes it possible to suppress absorptance of the first surface.

According to an embodiment of the present technology, a method for producing an optical part includes creating a part that includes a first surface and a second surface constituting a recessed section or a protruded section in cooperation with the first surface

Through atomic layer deposition (ALD), a multi-layer film is formed on the first surface and the second surface, the multi-layer film including an absorption layer for absorbing light and an upper layer including low refractive index material covering the absorption layer.

According to the method of producing the optical part, it is easily form the multi-layer film on the first and second surfaces through the ALD, the first and second surfaces constituting the recessed section or the protruded section. Therefore, it is possible to easily produce the optical part capable of suppressing generation of stray light.

According to an embodiment of the present technology, an image display apparatus includes a light source section and an image generation section.

The image generation section includes the optical part, and generates an image on the basis of light emitted from the light source section.

### Advantageous Effects of Invention

As described above, according to the present technology, it is possible to easily produce the optical part capable of suppressing generation of stray light. Note that, the effects described herein are not necessarily limited and may be any of the effects described in the present disclosure.

### BRIEF DESCRIPTION OF DRAWINGS

FIG. 1 is a diagram illustrating a configuration example of a head-mounted display (HMD) that is an image display apparatus according to an embodiment of the present technology.

FIG. 2 is a diagram for describing a principle of display of an image of the HMD.

FIG. 3 is a diagram schematically illustrating a field of view of a user who is wearing the HMD.

FIG. 4 is a schematic diagram illustrating a configuration example of a Fresnel lens.

FIG. 5 is a schematic diagram illustrating another configuration example of the Fresnel lens.

FIG. 6 is a cross-sectional view that schematically illustrates a configuration example of an antireflection film.

FIG. 7 is a diagram schematically illustrating a method of forming the antireflection film.

FIG. 8 is a diagram schematically illustrating respective light beams incident on a lens surface and a non-lens surface.

FIG. 9 is a table showing an example of dependency between reflectance, absorptance, and incident angles with regard to the antireflection film.

FIG. 10 is a table showing a simulation example of reflectance and absorptance of light incident on the lens surface and the non-lens surface.

FIG. 11 is graphs for describing effects of a lowermost layer including titanium dioxide (TiO₂).

FIG. 12 is a table showing an example of optical constants of absorption layers.

FIG. 13 is graphs showing characteristics of an antireflection film including another material.

FIG. 14 is graphs showing characteristics of an antireflection film including other material.

FIG. 15 is graphs showing characteristics of an antireflection film including other material.

FIG. 16 is photographs showing stray light evaluation examples.

FIG. 17 is photographs showing stray light evaluation examples.

FIG. 18 is photographs showing stray light evaluation examples.

### MODE(S) FOR CARRYING OUT THE INVENTION

Hereinafter, embodiments of the present technology will be described with reference to the drawings.

[Image Display Apparatus]

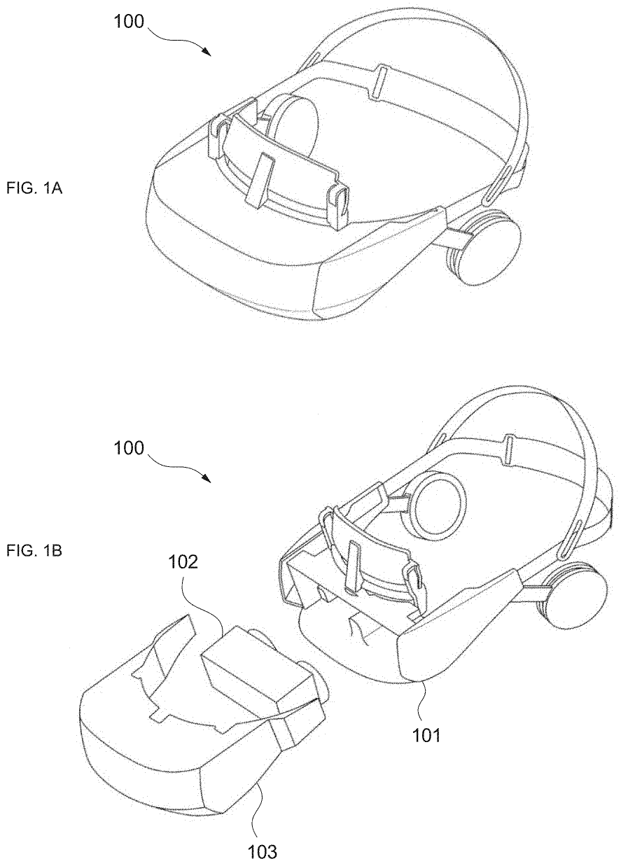

FIG. 1 is a diagram illustrating a configuration example of a head-mounted display (HMD) that is an image display apparatus according to an embodiment of the present technology. FIG. 1A is a perspective view that schematically illustrates an appearance of an HMD 100. FIG. 1B is a perspective view that schematically illustrates a situation in which the HMD 100 is disassembled.

The HMD 100 includes a mounted section 101, a display unit 102, and a cover section 103. The mounted section 101 is mounted on the head of a user. The display unit 102 is disposed in front of the eyes of the user. The cover section 103 is configured to cover the display unit 102. The HMD 100 is an immersive head-mounted display configured to cover the field of view of the user. When wearing the HMD 100, it is possible for the user to experience virtual reality (VR) or the like.

Note that, as an embodiment of the image display apparatus according to the present technology, it is possible to configure an apparatus other than the immersive HMD. For example, it is possible to configure a transmissive HMD for augmented reality (AR) or a head-up display (HUD) as embodiments of an image display apparatus according to the present technology. In addition, the present technology is applicable to various kinds of image display apparatuses.

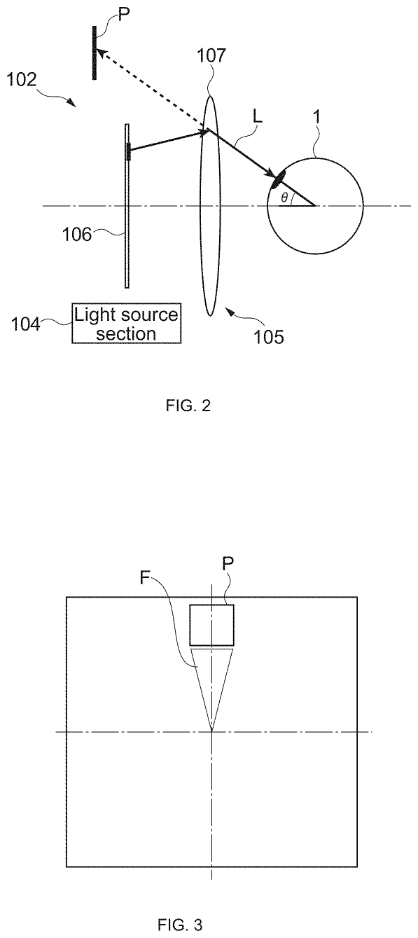

FIG. 2 is a diagram for describing a principle of display of an image of the HMD 100. FIG. 3 is a diagram schematically illustrating a field of view of a user who is wearing the HMD 100. The display unit 102 includes a light source section 104 and an image generation section 105 that generates an image on the basis of light emitted from the light source section 104.

For example, the light source section 104 includes a solid light source such as a light-emitting diode (LED) or a laser diode (LD). A specific configuration of the light source section 104, an installation position of the light source section 104, and the like are not limited. It is possible to arbitrarily design the light source section 104.

The image generation section 105 includes an image generation element 106 and a Fresnel lens 107. The image generation element 106 modulates light emitted from the light source section 104 on the basis of an image signal, and generates an image (image light) L. As the image generation element 106, it is possible to use a transmissive/reflective liquid crystal panel, a digital micromirror device (DMD), or the like.

The Fresnel lens 107 is provided between the image generation element 106 and the user, and projects the image light L generated by the image generation element 106. As illustrated in FIG. 2, the image light L is incident on an eyeball 1 of the user via the Fresnel lens 107. The user visually recognizes an image (virtual image) P including the image light L.

For example, when unnecessary light or the like that has deviated from a predetermined optical path designed in advance becomes stray light, the stray light is incident on the eyeball 1 of the user, and this results in reduction in quality of the image P. For example, it is assumed that a general Fresnel lens is used instead of the Fresnel lens 107 according to this embodiment. As illustrated in FIG. 2, it is assumed that the user quickly turns his/her gaze on a position above the center of the image generation element 106 at a predetermined angle (gaze movement angle) θ.

Subsequently, as illustrated in FIG. 3, the stray light generated in the general Fresnel lens may cause flare F in the field of view of the user. For example, it is highly possible that the flare F is generated in the case where reflection at a non-lens surface of the Fresnel lens is large.

In the example illustrated in FIG. 3, the flare F is generated between the center of the field of view and the image P that is appropriately displayed. The center of the field of view corresponds to the center of the image generation element 102. Therefore, the flare F is generated like an afterimage between a position of the gaze before moving the gaze and the image P that is in front of the gaze. Of course, the shape and the generation position of the flare F are not limited. In addition, the situation in which the flare F is generated is not limited to the case of quickly moving the gaze. The flare F may be generated in other situations. In any case, the flare F, a ghost, or the like may be generated when the stray light is incident on the eyeball 1, and this results in reduction in quality of the image P.

[Fresnel Lens]

The Fresnel lens 107 according to this embodiment is an embodiment of the optical part according to the present technology. The Fresnel lens 107 is capable of sufficiently suppressing generation of the stray light. Accordingly, it is possible to prevent generation of the flare F and the like as described above, and it is possible to display a high-quality image. In addition, it is extremely easy to produce the Fresnel lens 107 according to this embodiment. Details thereof will be described later.

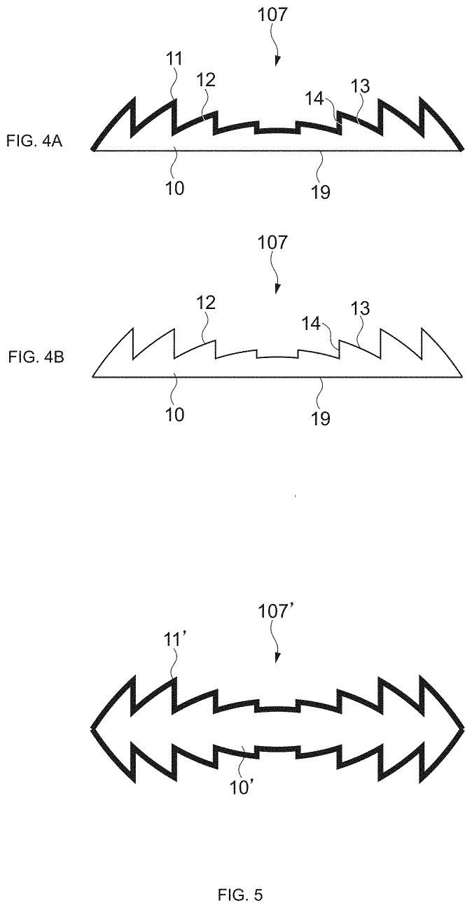

FIG. 4 is a schematic diagram illustrating a configuration example of the Fresnel lens 107 according to this embodiment. FIG. 4A is a diagram illustrating a lens section 10 and an antireflection film 11 that are included in the Fresnel lens 107. FIG. 4B is a diagram illustrating the lens section 10 before the antireflection film 11 is formed.

As illustrated in FIG. 4A, the Fresnel lens 107 includes the lens section 10 and the antireflection film 11. For example, the lens section 10 includes acrylic resin, epoxy resin, polycarbonate resin, cycloolefin polymer (COP) resin, or the like, and has a Fresnel lens shape.

As illustrated in FIG. 4B, a Fresnel lens pattern is formed on a lens main surface 12 of the lens section 10, and the Fresnel lens pattern has an uneven shape. In the example illustrated in FIG. 4B, a plurality of lens surfaces 13 and a plurality of non-lens surfaces 14 are formed. The lens surfaces 13 are arranged substantially in a concentric pattern, and the non-lens surfaces 14 connect the adjacent lens surfaces 13.

As a predetermined function, the lens surface 13 has a lens function related to incident light. Refractive indices of the lens section 10, the shapes of the lens surfaces 13, and the like are designed in a manner that light incident on the lens surfaces 13 goes along predetermined optical paths.

The non-lens surface 14 is a surface that does not have any function related to the incident light, and is a surface on which the image light L emitted from the image generation element 106 should not be incident. For example, stray light is generated if light is reflected by the non-lens surface 14.

As schematically illustrated in FIG. 2, the Fresnel lens 107 is disposed in a manner that the lens main surface 12 faces the image generation element 106. For example, the Fresnel lens 107 is disposed in a manner that the lens main surface 12 is substantially perpendicular to an emission direction of the image light L emitted from the image generation element 106. In such a way, the Fresnel lens 107 is disposed in a manner that the lens surfaces 13 face the optical paths of the image light L, and the non-lens surfaces 14 is substantially parallel to the emission direction. As a result, it is possible to suppress light incident on the non-lens surfaces 14.

The specific configuration of the lens section 10 is not limited. Any Fresnel pattern or the like may be formed. In addition, it is possible for the lens main surface 12 side to face the emission direction of the light, and it is also possible for a back surface 19 side opposite to the lens main surface 12 side to face the emission direction of the light. Note that, as illustrated in FIG. 5, the present technology is also applicable to a double-sided Fresnel lens 107′ in which the Fresnel lens pattern is formed on the both sides. In other words, by forming an antireflection film 11′ on a lens section 10′, it is possible to sufficiently suppress generation of stray light.

In this embodiment, the lens section 10 corresponds to an optical part. The lens surface 13 corresponds to a first surface. The non-lens surface 14 corresponds to a second surface constituting a recessed section or a protruded section in cooperation with the first surface. In this embodiment, both the recessed sections and the protruded sections are formed by the lens surfaces 13 and the non-lens surfaces 14 that are adjacent to each other. The present technology is not limited thereto. The present technology is also applicable to a case where the first and second surfaces form only the recessed sections, or a case where the first and second surfaces form only the protruded sections.

As illustrated in FIG. 4A, the antireflection film 11 is formed on the whole lens main surface 12 on which the Fresnel pattern is formed. In other words, the antireflection film 11 is formed on the first surfaces 13 and the second surfaces 14. The antireflection film 11 corresponds to a multi-layer film according to this embodiment. The antireflection film 11 absorbs light and prevents reflection.

[Antireflection Film]

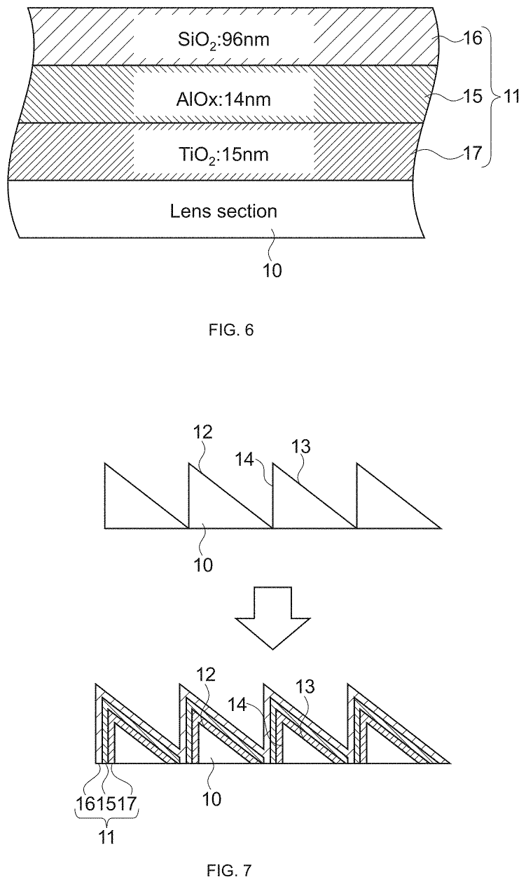

FIG. 6 is a cross-sectional view that schematically illustrates a configuration example of the antireflection film 11. To simplify the drawing, hatching of the lens section 10 is omitted in FIG. 6.

The antireflection film 11 includes three layers, which are an absorption layer 15, an uppermost layer 16, and a lowermost layer 17. The absorption layer 15 is a layer that absorbs light. In this embodiment, a layer including an oxide of aluminum (AlOx) having a thickness of 14 nm is formed. The absorption layer 15 achieves absorption of light.

The uppermost layer 16 includes low refractive material, and is stacked on the absorption layer 15. In this embodiment, a layer including silicon dioxide (SiO₂) is formed as the uppermost layer 16. The layer has a refractive index of 1.5 or less and a thickness of 96 nm. It is possible to prevent reflection of light when the uppermost layer 16 including low refractive material is stacked on the absorption layer 15. In this embodiment, the uppermost layer 16 corresponds to an upper layer that covers the absorption layer 15.

The lowermost layer 17 is a layer formed on the lens section 10, and is formed between the lens section 10 and the absorption layer 15. In this embodiment, a layer including titanium dioxide (TiO₂) is formed as the lowermost layer 17. The layer has a thickness of 15 nm. In this embodiment, the lowermost layer 17 corresponds to a lower layer.

FIG. 7 is a diagram schematically illustrating a method of forming the antireflection film 11. The antireflection film 11 is evenly formed on the whole lens main surface 12 having an uneven shape. In this embodiment, the antireflection film 11 is formed on the lens surfaces 13 and the non-lens surfaces 14 through atomic layer deposition (ALD).

The ALD is a scheme of forming atomic layers one by one, by repeating a cycle of supply of material and exhaust of the material. It is possible to form an oxide film by including oxygen in introduction gas, and it is possible to form a nitride film by including nitrogen in introduction gas. Since there is a correlation between a film thickness and the number of cycles of supply of material, it is possible to achieve even coating with the desired film thicknesses precisely along the uneven shape, by setting the number of cycles in a manner that the respective layers have desired film thicknesses.

In addition, when using a scheme of performing plasma degradation on the material to be supplied among ALD schemes, it is possible to form films at a temperature lower than thermal ALD. Therefore, this is advantageous to film formation at a temperature equal to or less than the upper temperature limit of resin material included in the lens section 10. Accordingly, it is possible to expand choice of resin material. Of course, it is also possible to perform the thermal ALD as long as resin material is tolerant of heat at a time of film formation.

In this embodiment, in a first step, a layer of titanium dioxide (TiO₂) having a thickness of 15 nm is formed. In a second step, a layer of an oxide of aluminum (AlOx) having a thickness of 14 nam is formed. In a third step, a layer of silicon dioxide (SiO₂) having a thickness of 96 nm is formed. In such a way, it is possible to form the antireflection film 11 including three layers, which are the absorption layer 15, the uppermost layer 16, and the lowermost layer 17, on the Fresnel lens pattern.

The first step to the third step are a process using a single ALD apparatus, and they can be sequentially executed while changing introduction gas and material to be supplied. In other words, it is possible to easily produce the Fresnel lens 107 according to this embodiment. For example, it is easy to manage the steps, it is possible to achieve a high yield, and it is possible to produce the Fresnel lens 107 at low cost.

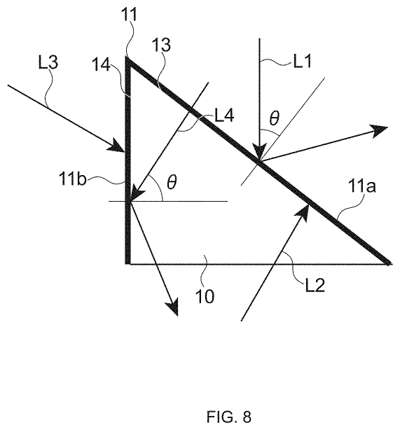

FIG. 8 is a diagram schematically illustrating respective light beams incident on the lens surface 13 and the non-lens surface 14. As illustrated in FIG. 8, an antireflection film 11 formed on the lens surface 13 is referred to as a first antireflection film 11a, and an antireflection film 11 formed on the non-lens surface 14 is referred to as a second antireflection film lib.

In addition, light incident on the first antireflection film 11a from an outside of the lens section 10 is referred to as lens surface external light L1, and light incident on the first antireflection film 11a from an inside of the lens section 10 is referred to as lens surface internal light L2. In addition, light incident on the second antireflection film 11b from the outside of the lens section 10 is referred to as non-lens surface external light L3, and light incident on the second antireflection film 11b from the inside of the lens section 10 is referred to as non-lens surface internal light L4.

The inventors focused on a fact that image light L emitted from the image generation element 106 is mainly incident on the lens surface 13 at small incident angles 19, and goes along predetermined optical paths. In other words, the inventors focused on a fact that, among the lens surface external light L1 and the lens surface internal light L2 illustrated in FIG. 8, light having a smaller incident angle θ is valid image light L, and small reflection and small light absorption (much of light is transmitted) are important.

On the other hand, it is highly possible that light incident on the non-lens surfaces 14 causes stray light. Therefore, it is necessary to suppress unnecessary reflection and achieve high light absorption. Here, the inventors found that light incident on the non-lens surfaces 14 at large incident angles θ is a main cause of the stray light. In other words, the inventors found that it is important to sufficiently absorb light having large incident angles among the non-lens surface external light L3 and the non-lens surface internal light L4 illustrated in FIG. 8. On the basis of the above-described findings, the antireflection film 11 according to this embodiment was developed.

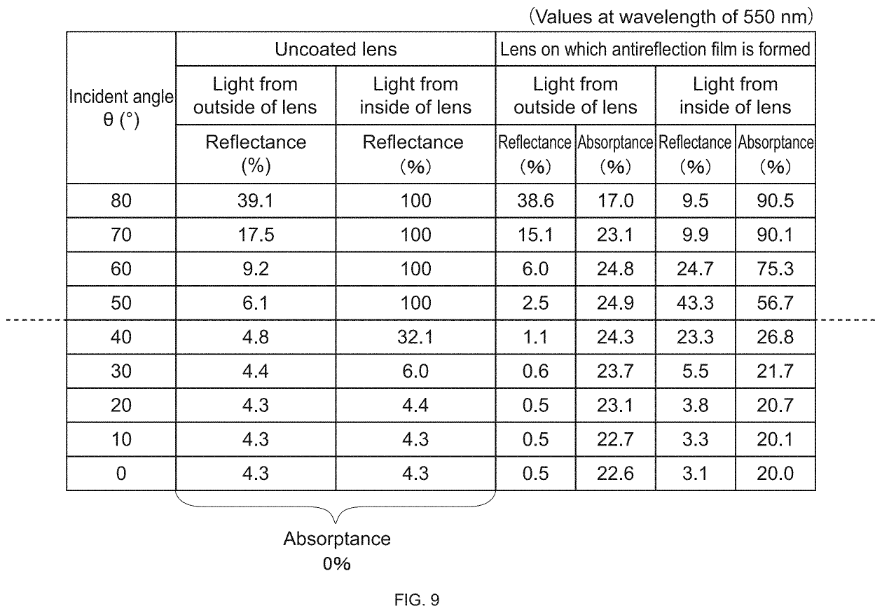

FIG. 9 is a table showing an example of dependency between reflectance, absorptance, and incident angles of the antireflection film 11. FIG. 9 also illustrates simulation results of an uncoated lens on which the antireflection film 11 is not formed. Here, characteristics related to light with a wavelength of 550 nm are shown.

When focusing on light having small incident angles θ such as light having incident angles θ of 0° to 40°, the lens on which the antireflection film is formed has lower reflectance than the uncoated lens, with regard to both light from the outside of the lenses (such as the lens surface external light L1 illustrated in FIG. 8) and light from the inside of the lenses (such as the lens surface internal light L2 illustrated in FIG. 8). Accordingly, in comparison with the uncoated lens, the lens on which the antireflection film is formed is capable of suppressing reflection of valid image light L incident on the lens surfaces 13.

In this embodiment, the reflectance is 1.1% or less with regard to the external light incident on the antireflection film 11 from the outside of the lens section 10 at the incident angles of 40° or less. Therefore, it is possible to sufficiently suppress loss of light and generation of stray light that are caused by reflection. Note that, sufficient effects can be obtained as long as reflectance is 4% or less with regard to the external light incident on the antireflection film 11 from the outside of the lens section 10 at the incident angles of 40° or less.

When focusing on light having large incident angles θ such as light having incident angles θ of 50° to 80°, the uncoated lens has higher reflectance as the incident angle θ of light from the outside of the lens increases. Since the uncoated lens has an absorptance of 0%, it is understood that much of the light enters the inside of the lens.

Regardless of its incident angles, the light from the inside of the lens has reflectance of 100%. Therefore, in the case of the uncoated lens, it is highly possible that reflection is repeated in the lens member and light is eventually emitted toward the outside of the lens as stray light.

In the case where the antireflection film 11 is formed, it is possible to absorb a certain amount of light from the outside of the lens (such as the non-lens surface external light L3 illustrated in FIG. 8). This makes it possible to suppress generation of stray light. It is possible to achieve extremely high absorptance with regard to light from the inside of the lens (such as the non-lens surface internal light L4 illustrated in FIG. 8). In this embodiment, it is possible to achieve absorptance of 56.7% or more. This makes it possible to sufficiently suppress generation of stray light. Note that, although the stray light is suppressed more as the absorptance gets higher, the difference in the stray light between the uncoated lens and the lens on which the antireflection film 11 is formed is recognized as long as the absorptance is approximately 40% or more.

On the other hand, absorptance is 22.6% with regard to the external light incident on the antireflection film 11 from the outside of the lens section 10 at an incident angle of 0°, and this is a relatively low value. As a result, it is possible to suppress loss caused by absorption of the valid image light L.

As described above, the antireflection film 11 according to this embodiment has a characteristic of absorbing light in accordance with an incident angle of the light. This makes it possible to suppress absorption of light incident on the lens surfaces 13 and increase absorption of light incident on the non-lens surfaces 14. For example, it is possible to set the absorptance in a manner that absorptance of the non-lens surface internal light L4 having incident angles θ of 50° or more is higher than absorptance of the lens surface external light L1 having an incident angle θ of approximately 0°. This makes it possible to suppress loss of valid image light L, and sufficiently suppress generation of stray light caused by the non-lens surface internal light L4 having the incident angles θ of 50 or more.

In addition, in the example illustrated in FIG. 9, the absorptance of the internal light incident on the antireflection film 11 from the inside of the lens section 10 gets higher as the incident angle θ increases. By utilizing such angular dependency, it is possible to sufficiently suppress generation of stray light caused by internal light having large incident angles θ.

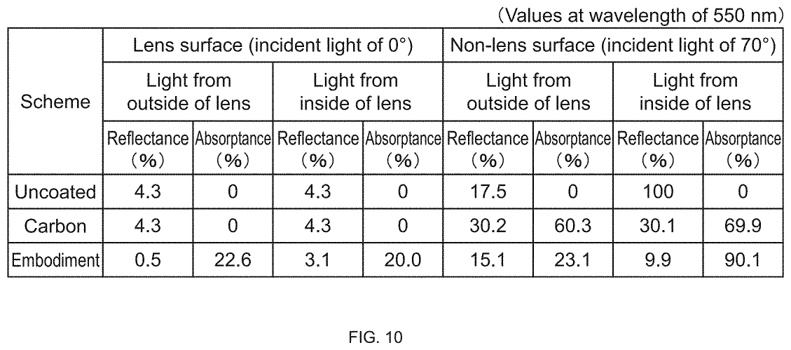

FIG. 10 is a diagram showing a simulation example of reflectance and absorptance of light incident on the lens surfaces 13 and the non-lens surfaces 14. FIG. 10 illustrates respective results obtained in the case of an uncoated lens, in the case of a lens in which carbon having a thickness of 200 mm is stacked only on the non-lens surfaces 14, and in the case of the lens according to this embodiment.

In addition, FIG. 10 illustrates results obtained in the case where light is incident on the lens surfaces 13 at an incident angle θ of 0°, and results obtained in the case where light is incident on the non-lens surfaces 14 at an incident angle of 70°. The results obtained in the case of the uncoated lens and in the case of the lens according to this embodiment show the same numerical values as the results illustrated in FIG. 9.

With regard to the lens surface 13, the result obtained in the case where carbon is stacked only on the non-lens surfaces 14 is the same as the result obtained in the case of the uncoated lens. With regard to the non-lens surfaces 14, absorptance obtained in the case where carbon is stacked only on the non-lens surfaces 14 is higher than absorptance obtained in the case of the uncoated lens. However, reflectance obtained in the case where carbon is stacked only on the non-lens surfaces 14 is approximately 30%, which is higher than reflectance obtained in the case of the uncoated lens. This is because the stacked carbon is a single carbon layer and this cannot prevent reflection. Therefore, it is difficult to suppress generation of stray light.

In this embodiment, it is possible to significantly improve light absorption of the non-lens surfaces 14 to 90.1%, while significantly reducing reflection at the lens surfaces 13 to 0.5% in comparison with the uncoated lens. In addition, it is possible to reduce reflection at the non-lens surfaces 14 to less than reflection at the uncoated lens. This makes it possible to sufficiently suppress generation of stray light.

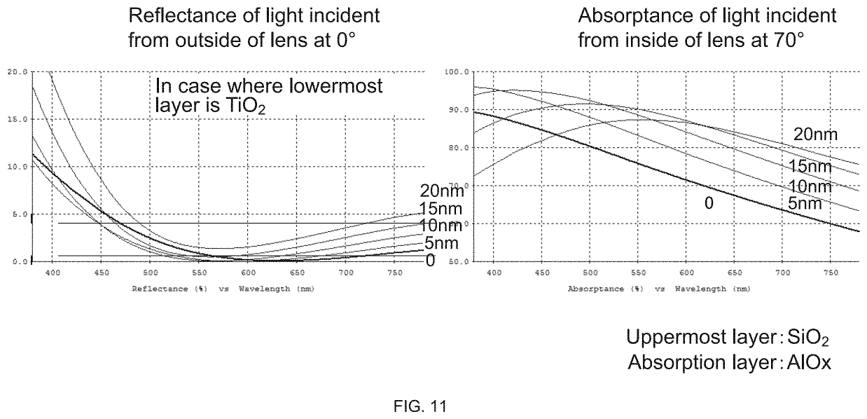

FIG. 11 is graphs for describing effects of the lowermost layer 17 including titanium dioxide (TiO₂). A graph on the left side shows reflectance of external light having an incident angle θ of 0°. A graph on the right side shows reflectance of internal light having an incident angle θ of 70°. FIG. 11 shows results obtained in the cases of the lowermost layers 17 having different thicknesses. Note that, in the graph, a line representing a thickness of 0 nm corresponds to reflectance obtained in the case where the lowermost layer 17 is not formed.

For example, in the graph on the left side, reflectance of light having wavelength of 550 nm is focused on. Even in the case where the lowermost layer 17 is not formed, the reflectance of external light having an incident angle θ of 0° is sufficiently small. Even in the case where the lowermost layer 17 is formed, the reflectance does not vary from the case where the lowermost layer 17 is not formed, regardless of the thickness of the lowermost layer 17. In other words, the reflectance to the external light having a small incident angle θ is not affected by formation of the lowermost layer 17.

With reference to the graph on the right side, absorptance of internal light having an incident angle θ of 70° is significantly improved when the lowermost layer 17 is formed. In other words, when the lowermost layer 17 is formed, it is possible to improve absorptance of internal light having a large incident angle θ while substantially maintaining the reflectance of external light having a small incident angle θ. This makes it possible to suppress loss of valid image light L, and sufficiently suppress generation of stray light.

Note that, as illustrated in the graph on the right side, high absorptance of internal light having an incident angle θ of 70° is achieved even in the case where the lowermost layer 17 is not formed. Therefore, it is possible to suppress loss of valid light, and sufficiently suppress generation of stray light even in the case where the lowermost layer 17 is not formed. Embodiments of the multi-layer film according to the present technology also include the configuration in which the lowermost layer 17 is not formed, such as an antireflection film including two layers, which are the absorption layer 15 and the uppermost layer 16.

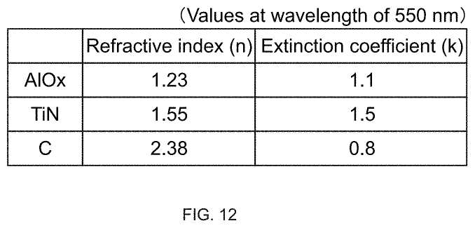

FIG. 12 is a table showing an example of optical constants of absorption layers 15. It is possible to sufficiently suppress generation of stray light when a layer including an oxide of aluminum (AlOx) having a refractive index of n=1.23 and an extinction coefficient k=1.1 is formed as the absorption layer 15.

For example, an oxidation process of the oxide of aluminum (AlOx) is adjusted such that the extinction coefficient k becomes approximately 1. For example, an oxygen addition amount is adjusted such that AlOx satisfies 0<x<1.5. This makes it possible to achieve appropriate light absorbability. Note that, the appropriate light absorbability and antireflection property are not achieved when the extinction coefficient k is too small or too large. For example, it is sufficient to set the extinction coefficient k while using a predetermined range around 1 as an appropriate range. A specific numerical value and the like of the appropriate range are not limited. Any range may be set in a manner that appropriate effects can be achieved.

When the thickness of the absorption layer 15 is increased, the absorptance of the non-lens surfaces 14 is improved. However, an amount of absorption by the lens surfaces 13 is also increased. For example, when the absorption layer has a thickness of 5 nm, the absorptance by the lens surfaces 13 falls within a range of approximately 10 to 20%. When the absorption layer has a thickness of 25 nm, the absorptance is increased to approximately 20 to 50%, and this results in large loss caused by absorption of valid image light L.

In this respect, it is possible to suppress generation of stray light by setting the thickness of the absorption layer 15 in a range of 5 nm or more and 25 nm or less. For example, sufficient effects are obtained when the thickness of the absorption layer 15 is set in a range of 5 nm or more and 15 nm or less. Of course, the thickness of the absorption layer 15 is not limited thereto. Any range may be set as a valid setting range.

The extinction coefficient k varies depending on material of the absorption layer 15. Therefore, a relation between thickness and absorptance varies depending on film formation processes. In this respect, sufficient effects are also obtained by setting the thickness of the absorption layer 15 in the range of 5 nm or more and 25 nm or less, for example.

As the absorption layer 15, it is also possible to use a layer including an oxide of other metal. Alternatively, it is possible to use carbon (C) or a metal nitride such as titanium nitride (TiN). As illustrated in FIG. 12, an absorption layer including titanium nitride (TiN) having a refractive index of n=1.55 and an extinction coefficient k=1.5, and an absorption layer including carbon (C) having a refractive index of n=2.38 and an extinction coefficient k=0.8 are formed. In these cases, it is also possible to sufficiently suppress generation of stray light. Note that, as described above, it is possible to easily form the layer of metal nitride through the ALD.

For the uppermost layer 16, low refractive material is used in view of antireflection property. Typically, material having a refractive index of 1.5 or less is used. However, the refractive index is not limited thereto. Material having a refractive index of more than 1.5 may be used as long as the appropriate antireflection property is achieved. Of course, the material is not limited to silicon dioxide (SiO₂). Other material such as magnesium fluoride (MgF₂) may be used.

Sometimes it is necessary to adjust the thickness of the uppermost layer 16 in accordance with the material of the absorption layer 15 and the material of the lowermost layer 17. The effects are achieved by setting the thickness in a range of 50 nm or more and 150 nm or less. In addition, sufficient effects are achieved by setting the thickness of the uppermost layer 16 in a range of 70 nm or more and 100 nm or less. Of course, the thickness of the uppermost layer 16 is not limited thereto. Any range may be set as a valid setting range.

When a layer including material having a refractive index of 1.5 or more is formed as the lowermost layer 17, it is possible to improve absorptance of internal light incident on the non-lens surfaces 14 at large incident angles θ. The thickness may be appropriately set in a manner that high absorptance of the internal light by the non-lens surfaces 14 is obtained. For example, in the case where the lowermost layer 17 including titanium dioxide (TiO₂) is formed like this embodiment, sufficient effects are achieved by setting the thickness of the lowermost layer 17 to approximately 15 nm as illustrated in FIG. 11.

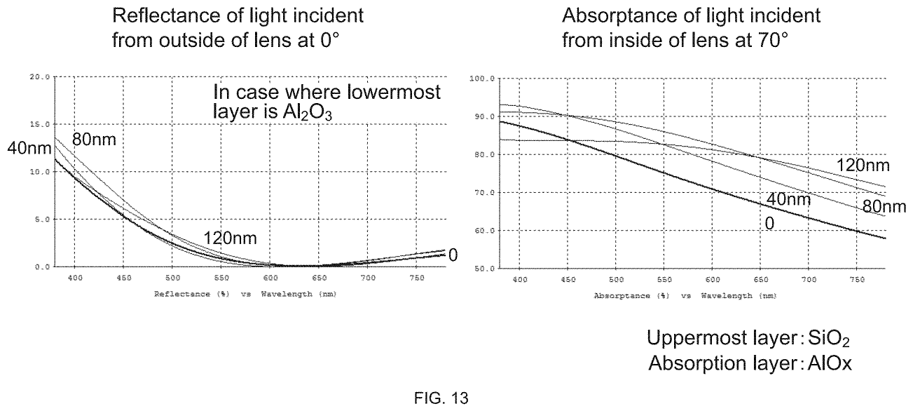

FIG. 13 to FIG. 15 are graphs showing characteristics of the antireflection film 11 including other material. FIG. 13 is graphs showing reflectance obtained in the case where a layer including aluminium oxide (Al₂O₃) is formed as the lowermost layer 17. Even in the case where the lowermost layer 17 including aluminium oxide (Al₂O₃) is formed, it is possible to sufficiently reduce reflectance of external light incident on the lens surfaces 13 at an incident angle θ of 0°, and improve absorptance of internal light incident on the non-lens surfaces 14 at an incident angle θ of 70°. In the example illustrated in FIG. 13, the highest absorptance is obtained and excellent effects are achieved when the lowermost layer 17 has a thickness of approximately 80 nm (see wavelength of 550 nm).

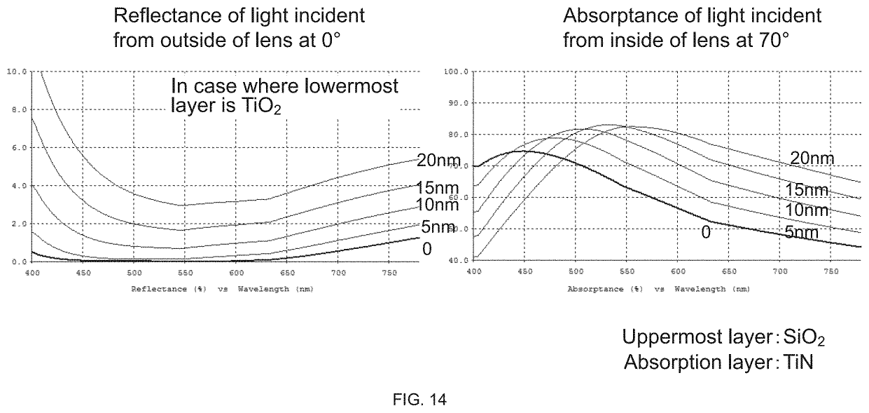

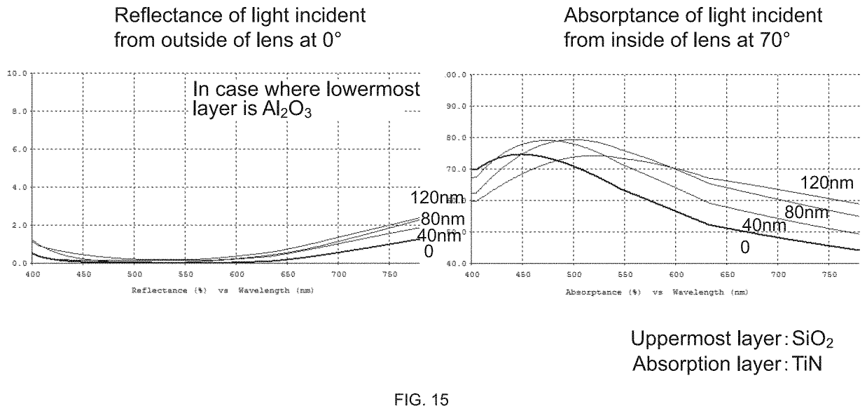

FIG. 14 is graphs showing a case where an absorption layer 15 including titanium nitride (TiN) and a lowermost layer 17 including titanium dioxide (TiO₂) are formed. In addition, FIG. 15 is graphs showing a case where an absorption layer 15 including titanium nitride (TiN) and a lowermost layer 17 including aluminium oxide (Al₂O₃) are formed.

Such antireflection films also achieve substantially similar effects. In the example illustrated in FIG. 14, excellent effects are achieved when the lowermost layer 17 including titanium dioxide (TiO₂) has a thickness of approximately 15 nm. In addition, in the example illustrated in FIG. 15, excellent effects are achieved when the lowermost layer 17 including aluminium oxide (Al₂O₃) has a thickness of approximately 80 nm. In other words, they have the characteristics similar to the examples illustrated in FIG. 11 and FIG. 13.

For the lowermost layer 17, material other than titanium dioxide (TiO₂) or aluminium oxide (Al₂O₃) may also be used. In addition, the refractive index is not limited to the range of 1.5 or more. Sometimes it is necessary to adjust the thickness in accordance with material or the like to be used. However, sufficient effects are achieved by setting the thickness of the lowermost layer 17 in a range of 10 nm or more and 100 nm or less. Of course, the thickness of the lowermost layer 17 is not limited thereto. Any range may be set as a valid setting range.

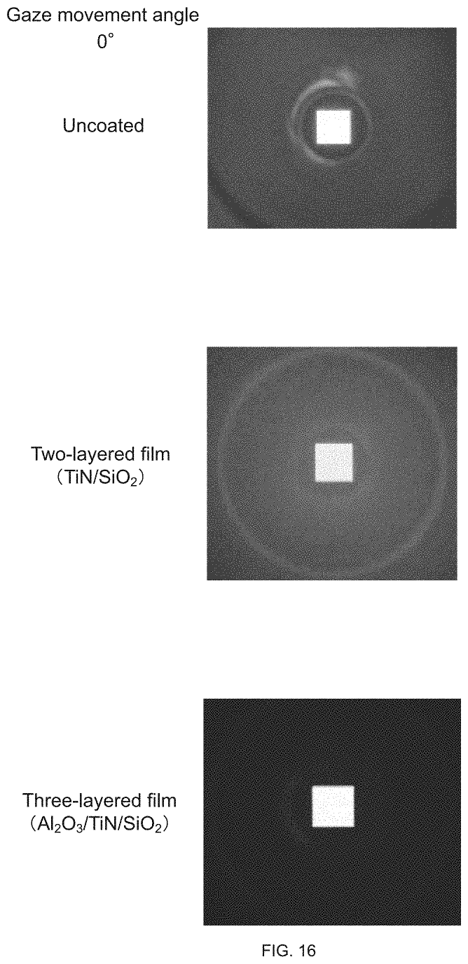

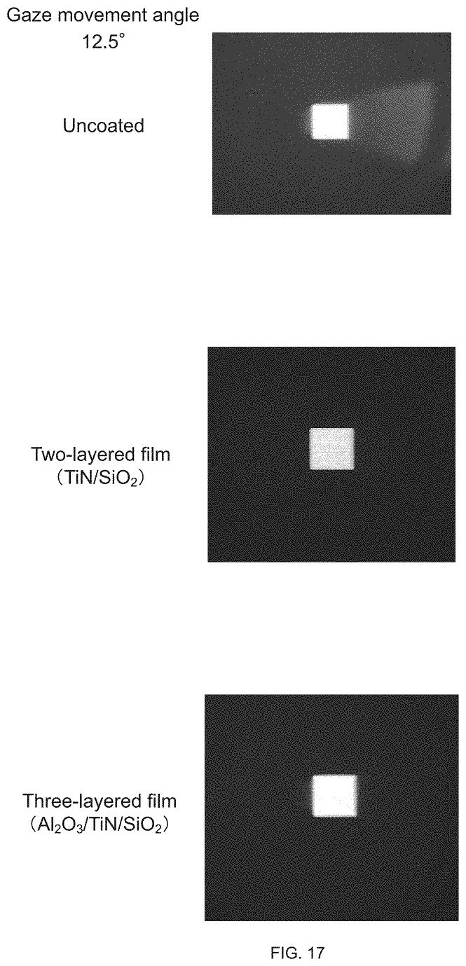

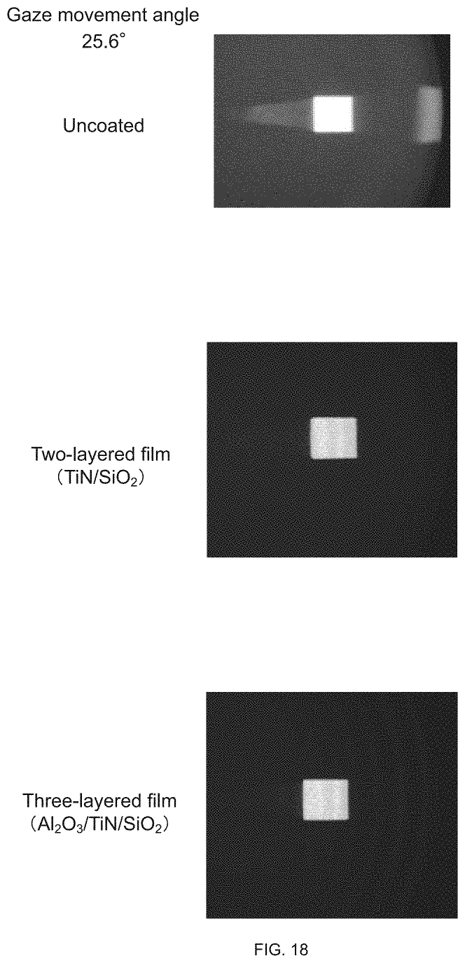

FIG. 16 to FIG. 18 are photographs showing stray light evaluation examples. Evaluation of light having wavelength of 550 nm is made by using the configuration that is schematically illustrated in FIG. 2. As illustrated in FIG. 16 to FIG. 18, it is evaluated whether flare is generated, and amounts of generated flare are evaluated with regard to various gaze movement angles of the user while using each of the uncoated lens, a lens with a two-layered antireflection film, and a lens with a three-layered antireflection film. The various gaze movement angles are 0°, 12.5°, and 25.6°.

At every gaze movement angles, much flare is generated in the case of the uncoated lens. Therefore, it is understood that much stray light is generated.

The two-layered antireflection film 11 is configured to include an absorption layer (TiN) and an uppermost layer (SiO₂) without a lowermost layer. The absorption layer (TiN) has a thickness of 7 nm, and the uppermost layer (SiO₂) has a thickness of 70 nm. Reflectance is 0.8% or less with regard to light having wavelength of 550 nm and incident angles of 0 to 40°. Absorptance of external light having an incident angle of 0° is 24%, and absorptance of internal light having an incident angle of 50° is 46%. As illustrated in FIG. 16 to FIG. 18, it is understood that flare is reduced when the two-layered antireflection film is formed. In other words, it is understood that generation of stray light is suppressed.

The three-layered antireflection film 11 is configured to include a lowermost layer (Al₂O₃), an absorption layer (TiN), and an uppermost layer (SiO₂). The lowermost layer (Al₂O₃) has a thickness of 50 nm, and the absorption layer (TiN) has a thickness of 6 nm. In addition, the uppermost layer (SiO₂) has a thickness of 80 nm. Reflectance is 0.9% or less with regard to light having wavelength of 550 nm and incident angles of 0 to 40°. Absorptance of external light having an incident angle of 0° is 20%, and absorptance of internal light having an incident angle of 50° is 53%.

As illustrated in FIG. 16 to FIG. 18, it is understood that flare is reduced more when the three-layered antireflection film 11 is formed. This is because formation of the lowermost layer 17 increases the absorptance of internal light having an incident angle of 50° by approximately 10% in comparison with the two-layered antireflection film 11. The evaluation results show the stray light reduction effect obtained by forming the lowermost layer 17.

Note that, in the above description, the configuration and the working effects of the Fresnel lens 107 on which the antireflection film 11 is formed according to the present technology have been described above with reference to the results related to the light having wavelength of 550 nm. Of course, it is also possible to achieve similar effects in the case of light having another wavelength, by forming the antireflection film 11 including the absorption layer 15, the uppermost layer 16, and the lowermost layer 17 on the lens surfaces 13 and the non-lens surfaces 14. For example, by appropriately setting various materials, thickness, and the like of the absorption layer 15, the uppermost layer 16, and the lowermost layer 17, it is possible to achieve similar effects related to any light included in a visible light range. Of course, the same applies to the two-layered antireflection film 11 in which the lowermost layer 17 is not formed.

As described above, the antireflection film 11 is formed on the lens surfaces 13 and the non-lens surfaces 14 of the Fresnel lens 107 according to this embodiment. The antireflection film 11 includes the absorption layer 15 for absorbing light and the uppermost layer 16 including low refractive index material covering the absorption layer 15. This makes it possible to absorb light and prevent reflection on the lens surfaces 13 and the non-lens surfaces 14, and it is possible to sufficiently suppress generation of stray light. In addition, it is easy to produce the Fresnel lens 107 because it is only necessary to form the same antireflection film 11 on the lens surfaces 13 and the non-lens surfaces 14.

In the method for fabricating a Fresnel lens described in Patent Literature 1, the primary films such as AL is formed only on the lens surfaces through oblique evaporation, and then the light absorbing film such as carbon is formed on the whole surface through sputtering. Subsequently, the Fresnel lens is soaked in alkali solution, and the primary films is removed. Therefore, it is possible to fabricate a Fresnel lens in which the light absorbing films remain only on the non-lens surfaces.

This fabrication method requires high cost because the process includes three steps that use different apparatuses. In addition, since only the light absorbing films are formed on the non-lens surfaces, such a Fresnel lens has a higher reflectivity particularly related to light incident on the non-lens surfaces from the outside, in comparison with an uncoated lens. Therefore, much of stray light is generated. In addition, the lens surfaces do not have antireflection property. Therefore, such a Fresnel lens cannot handle stray light generated from the lens surfaces.

In this embodiment, the whole lens main surface 12 is coated with the multi-layered antireflection film 11 including the absorption layer 15 as a portion thereof. This makes it possible to suppress reflection of light incident on the non-lens surfaces 14 from the outside at large incident angles, and prevent reflection of light incident on the lens surfaces 13 at small incident angles. In addition, it is possible to sufficiently absorb light incident on the non-lens surfaces 14 from the inside at large incident angles. This makes it possible to sufficiently suppress generation of stray light.

### Another Embodiment

The present technology is not limited to the above-described embodiment. Various other embodiments are possible.

As illustrated in FIG. 9 and FIG. 10, it is possible to absorb a modicum of light having small incident angles θ in the case where the antireflection film 11 according to the present technology is formed. Accordingly, valid image light that has passed through the lens surfaces 13 is also absorbed. Therefore, a little amount of light is lost.

Therefore, it is effective to improve transmittance of the region formed on the lens surfaces 13 of the antireflection film 11, that is, transmittance of the first antireflection film 11a illustrated in FIG. 8. For example, in the case where a metal oxide such as an oxide of aluminum (AlOx) is used as the absorption layer 15, the absorption layer 15 is configured in a manner that an oxygen addition amount of the absorption layer 15 in regions formed on the lens surfaces 13 (the absorption layer 15 in the first antireflection film 11a) is higher than an oxygen addition amount of the absorption layer 15 in regions formed on the non-lens surfaces 14 (the absorption layer 15 in the second antireflection film 11b). This makes it possible to reduce an extinction coefficient of the absorption layer 15 in the first antireflection film 11a, and suppress absorptance. As a result, it is possible to improve transmittance of the first antireflection film 11a.

Examples of the method for controlling the oxygen addition amount include anisotropic ashing. For example, the antireflection film 11 is formed through the ALD or the like, and then an ashing apparatus performs the anisotropic ashing. Collision of reactive gas is suppressed by reducing the reactive gas such as oxygen and lengthening a mean free path. This makes it possible to control process conditions in a manner that an incident angle component in an electric-field direction that is generated to be perpendicular to the optical part is dominant.

This makes it possible to suppress a reaction in the perpendicular plane that is parallel to the electric-field direction, and selectively accelerate oxidation of planes other than the perpendicular plane. As a result, oxidation of the absorption layer 15 that is formed on the non-lens surfaces 14 serving as the perpendicular plane is not accelerated, but oxidation of the absorption layer 15 formed on the lens surfaces 13 is accelerated. This makes it possible to selectively increase the oxygen addition amount of the absorption layer 15 in the first antireflection film 11a. As described above, through the anisotropic ashing, it is possible to selectively reduce the absorptance of the absorption layer 15 formed on the lens surfaces 13.

Note that, it is also possible to first form the absorption layer 15, perform the anisotropic ashing, and then form the uppermost layer 16. In this case, although the processes get a little complicated, accuracy of control of the absorptance (transmittance) is improved. In addition, it is also possible to control a nitrogen addition amount through the anisotropic ashing in the case where a metal nitride is used as the absorption layer 15.

In the above description, the ALD has been used as an example of the method for forming the antireflection film 11 on the uneven lens main surface 12. However, the method is not limited thereto. It is possible to use another method such as evaporation, sputtering, or chemical vapor deposition (CVD). Depending on the shape of unevenness, it is possible to form the antireflection film 11 on the whole surface by using such a method.

In the above description, the case where “the upper layer” according to the present technology corresponds to the uppermost layer 16 and “the lower layer” according to the present technology corresponds to the lowermost layer 17 has been described as an example. However, the present technology is not limited thereto. It is also possible to form another layer on “the upper layer”, and it is also possible to form another layer below “the lower layer”. In addition, it is also possible to form another layer between “the upper layer” and “the absorption layer”, and between “the lower layer” and “the absorption layer”.

In the above description, the Fresnel lens 107 that includes the lens surfaces 13 (the first surface) having the lens function and the non-lens surfaces 14 (the second surface) having no lens function has been used as an example. However, the present disclosure is not limited thereto. The present technology is applicable to other lenses and other optical parts. The present technology is applicable to a case where the first and second surfaces do not have the predetermined functions, and a case where the both surfaces have the predetermined functions oppositely. For example, examples of the case to which the present technology is applicable include various configurations such as a case where both the first and second surfaces have the lens functions, a case where the first surface has the lens function and the second surface has another function, and the like.

It is possible to form the antireflection film 11 according to the present technology on the back surface 19 illustrated in FIG. 4. In other words, it is possible to form “the multi-layer film” on a surface other than “the first surface” or “the second surface”.

The present technology is also applicable to a case of using synthetic light obtained by synthesizing a plurality of light beams included in a predetermined wavelength band. For example, by appropriately setting materials, thicknesses, and the like of “the absorption layer”, “the upper layer”, and “the lower layer”, it is also possible to achieve the above described effects even with respect to while light obtained by synthesizing respective light beams of R, G, and B included in the visible light range. For example, “the multi-layer film” may be formed on the basis of a simulation result of the synthetic light, or “the multi-layer film” may be formed on the basis of a predetermined wavelength light beam included in the synthetic light. In addition, any method can be used for forming “the multi-layer film” according to the present technology. Of course, the same applies to a case where “the lower layer” is not formed.

Out of the feature parts according to the present technology described above, at least two feature parts can be combined. That is, the various feature parts described in the respective embodiments may be arbitrarily combined irrespective of the embodiments. Further, various effects described above are merely examples and are not limited, and other effects may be exerted.

Note that, the present technology may also be configured as below.

(1) An optical part including:

an optical section that includes a first surface and a second surface constituting a recessed section or a protruded section in cooperation with the first surface; and

a multi-layer film that is formed on the first surface and the second surface and that includes an absorption layer for absorbing light and an upper layer including low refractive index material covering the absorption layer.

(2) The optical part according to (1),

in which the first surface has a predetermined function related to incident light.

(3) The optical part according to (1) or (2),

in which the multi-layer film has optical absorption property depending on an incident angle of the light.

(4) The optical part according to any one of (1) to (3),

in which the multi-layer film has higher absorptance with respect to internal light that is incident on the multi-layer film from an inside of the optical section at the incident angle of 50° or more, than absorptance with respect to external light that is incident on the multi-layer film from an outside of the optical section at the incident angle of approximately 0°.

(5) The optical part according to any one of (1) to (4),

in which the multi-layer film has higher absorptance with respect to internal light that is incident on the multi-layer film from an inside of the optical section, as the incident angle increases.

(6) The optical part according to any one of (1) to (5),

in which the multi-layer film has reflectance of 4% or less with respect to external light that is incident on the multi-layer film from an outside of the optical section at the incident angle of 40° or less.

(7) The optical part according to any one of (1) to (6),

in which the absorption layer includes a metal oxide, a metal nitride, or carbon.

(8) The optical part according to any one of (1) to (7),

in which the absorption layer includes an oxide of aluminum, or titanium nitride.

(9) The optical part according to any one of (1) to (8),

in which the absorption layer has a thickness of 5 nm or more and 25 nm or less.

(10) The optical part according to any one of (1) to (9),

in which the upper layer includes the low refractive index material having a refractive index of 1.5 or less.

(11) The optical part according to any one of (1) to (10),

in which the upper layer has a thickness of 50 nm or more and 150 nm or less.

(12) The optical part according to any one of (1) to (11),

in which the multi-layer film includes a lower layer interposed between the optical section and the absorption layer.

(13) The optical part according to any one of (1) to (12),

in which the lower layer includes material having a refractive index of 1.5 or more.

(14) The optical part according to any one of (1) to (13),

in which the lower layer has a thickness of 10 nm or more and 100 nm or less.

(15) The optical part according to any one of (1) to (14),

in which the optical section is a Fresnel lens including a lens surface that is the first surface, and a non-lens surface that is the second surface.

(16) The optical part according to any one of (1) to (15),

in which the absorption layer is a metal oxide, and an oxygen addition amount in a region formed on the first surface is larger than an oxygen addition amount in a region formed on the second surface.

(17) A method for producing an optical part, the method including:

creating a part that includes a first surface and a second surface constituting a recessed section or a protruded section in cooperation with the first surface; and

forming, through atomic layer deposition (ALD), a multi-layer film on the first surface and the second surface, the multi-layer film including an absorption layer for absorbing light and an upper layer including low refractive index material covering the absorption layer.

(18) An image display apparatus including:

a light source section; and

an image generation section that includes an optical part including
an optical section that includes a first surface and a second surface constituting a recessed section or a protruded section in cooperation with the first surface, and
a multi-layer film that is formed on the first surface and the second surface and that includes an absorption layer for absorbing light and an upper layer including low refractive index material covering the absorption layer,

the image generation section generating an image on the basis of light emitted from the light source section.

### REFERENCE SIGNS LIST

10, 10′ lens section
11, 11′ antireflection film
11a first antireflection film
11b second antireflection film
13 lens surface
14 non-lens surface
15 absorption layer
16 uppermost layer
17 lowermost layer
100 HMD
104 light source section
105 image generation section
107 Fresnel lens
107′ double-sided Fresnel lens

1. An optical part comprising:
an optical section that includes a first surface and a second surface constituting a recessed section or a protruded section in cooperation with the first surface; and
a multi-layer film that is formed on the first surface and the second surface and that includes an absorption layer for absorbing light and an upper layer including low refractive index material covering the absorption layer.

2. The optical part according to claim 1,
wherein the first surface has a predetermined function related to incident light.

3. The optical part according to claim 1,
wherein the multi-layer film has optical absorption property depending on an incident angle of the light.

4. The optical part according to claim 1,
wherein the multi-layer film has higher absorptance with respect to internal light that is incident on the multi-layer film from an inside of the optical section at the incident angle of 50° or more, than absorptance with respect to external light that is incident on the multi-layer film from an outside of the optical section at the incident angle of approximately 0°.

5. The optical part according to claim 1,
wherein the multi-layer film has higher absorptance with respect to internal light that is incident on the multi-layer film from an inside of the optical section, as the incident angle increases.

6. The optical part according to claim 1,
wherein the multi-layer film has reflectance of 4% or less with respect to external light that is incident on the multi-layer film from an outside of the optical section at the incident angle of 40° or less.

7. The optical part according to claim 1,
wherein the absorption layer includes a metal oxide, a metal nitride, or carbon.

8. The optical part according to claim 1,
wherein the absorption layer includes an oxide of aluminum, or titanium nitride.

9. The optical part according to claim 1,
wherein the absorption layer has a thickness of 5 nm or more and 25 nm or less.

10. The optical part according to claim 1,
wherein the upper layer includes the low refractive index material having a refractive index of 1.5 or less.

11. The optical part according to claim 1,
wherein the upper layer has a thickness of 50 nm or more and 150 nm or less.

12. The optical part according to claim 1,
wherein the multi-layer film includes a lower layer interposed between the optical section and the absorption layer.

13. The optical part according to claim 1,
wherein the lower layer includes material having a refractive index of 1.5 or more.

14. The optical part according to claim 1,
wherein the lower layer has a thickness of 10 nm or more and 100 nm or less.

15. The optical part according to claim 1,
wherein the optical section is a Fresnel lens including a lens surface that is the first surface, and a non-lens surface that is the second surface.

16. The optical part according to claim 1,
wherein the absorption layer is a metal oxide, and an oxygen addition amount in a region formed on the first surface is larger than an oxygen addition amount in a region formed on the second surface.

17. A method for producing an optical part, the method comprising:
creating a part that includes a first surface and a second surface constituting a recessed section or a protruded section in cooperation with the first surface; and
forming, through atomic layer deposition (ALD), a multi-layer film on the first surface and the second surface, the multi-layer film including an absorption layer for absorbing light and an upper layer including low refractive index material covering the absorption layer.

18. An image display apparatus comprising:
a light source section; and
an image generation section that includes an optical part including
an optical section that includes a first surface and a second surface constituting a recessed section or a protruded section in cooperation with the first surface, and
a multi-layer film that is formed on the first surface and the second surface and that includes an absorption layer for absorbing light and an upper layer including low refractive index material covering the absorption layer,
the image generation section generating an image on a basis of light emitted from the light source section.
